(19) United States
(12) Patent Application Publication
(10) Pub. No.: US 2023/0156991 A1
(43) Pub. Date: May 18, 2023

(54) COMPONENT PLACEMENT SYSTEMS, MULTI-PIPETTE PLACEMENT HEADS, AND METHODS OF USING THE SAME

(71) Applicant: Kulicke & Soffa Netherlands B.V., Eindhoven (NL)

(72) Inventors: Roy Brewel, Eindhoven (NL); Richard A. Van Der Burg, Eindhoven (NL)

(21) Appl. No.: 17/985,023

(22) Filed: Nov. 10, 2022

Related U.S. Application Data
(60) Provisional application No. 63/279,461, filed on Nov. 15, 2021.

(51) Int. Cl. H05K 13/04; H05K 13/08

(52) U.S. Cl. CPC H05K 13/041; H05K 13/0411; H05K 13/0409; H05K 13/0406; H05K 13/082; H05K 13/0882

(57) ABSTRACT

A component placement system is provided. The component placement system includes a placement head including a plurality of pipettes. Each of the plurality of pipettes is configured to pick and place components. The placement head includes a plurality of controllers, each of the plurality of controllers being configured to control a respective one of the plurality of pipettes.

### CROSS-REFERENCE TO RELATED APPLICATION

This application claims the benefit of U.S. Provisional Application No. 63/279,461, filed Nov. 15, 2021, the content of which is incorporated herein by reference.

### FIELD

The invention relates to component placement systems, and more particularly, to improved component placement systems including placement heads having a plurality of pipettes, and methods of using the same.

### BACKGROUND

In the electronics assembly industry, pick and place systems (i.e., component placement systems) are used for the placement of electronic components. In certain placement systems, a plurality of tools (e.g., pick up tools, pipettes, nozzles, etc.) may be carried by a single placement head. Thus, a plurality of electronic components (each carried by a distinct tool) may be carried at the same time by the placement head.

It would be desirable to provide improved component placement systems that overcome one or more of the deficiencies of conventional placement systems including as related to performance, accuracy, speed of operation.

### SUMMARY

According to an exemplary embodiment of the invention, a component placement system is provided. The component placement system includes a placement head including a plurality of pipettes. Each of the plurality of pipettes is configured to pick and place components. The placement head includes a plurality of controllers, each of the plurality of controllers being configured to control a respective one of the plurality of pipettes.

According to another exemplary embodiment of the invention, another component placement system is provided. The component placement system includes a placement head including a plurality of placement assemblies. Each of the plurality of placement assemblies includes (i) a controller; (ii) a pipette; (iii) a rotary encoder for detecting a rotary position of the pipette; and (iv) a z-axis position encoder for detecting a z-axis position of the pipette. For example, such a rotary encoder may detect a rotary position of the respective one of the plurality of pipettes (e.g., see rotary encoder 160 in FIG. 3A). For example, part of the rotary encoder may be on the pipette (e.g., on the shaft of the pipette, or some rotating element carrying the pipette).

According to yet another exemplary embodiment of the invention, another component placement system is provided. The component placement system includes a placement head including a plurality of placement assemblies. Each of the plurality of placement assemblies includes (i) a controller, (ii) a pipette, and (iii) a force sensor for detecting an impact force of the pipette during placement of a component. For example, such a force sensor may detect an impact force of the respective one of the plurality of pipettes during placement of a component (e.g., see force sensor 164 in FIG. 3A).

Aspects of the invention also relate to methods of using the aforementioned component placement systems, or any component placement system within the scope of the invention. For example, according to yet another exemplary embodiment of the invention, a method of operating a component placement system is provided. The method includes the steps of: providing a placement head including a plurality of pipettes and a plurality of controllers, each of the plurality of controllers being configured to control a respective one of the plurality of pipettes; collecting a plurality of components with the plurality of pipettes; and placing the plurality of components with the plurality of pipettes.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 is a block diagram side view illustrating a component placement system in accordance with an exemplary embodiment of the invention;

FIGS. 2A-2C are perspective views of various placement heads in accordance with various exemplary embodiments of the invention;

FIG. 3A is a detailed block diagram view of the placement head of FIG. 2A, along with additional elements of a component placement system, in accordance with an exemplary embodiment of the invention;

FIG. 3B is a perspective view of a elements of a z-axis motion system used in connection with placement head of FIG. 3A, in accordance with an exemplary embodiment of the invention;

FIGS. 4A-4B are block diagram top views illustrating additional component placement systems in accordance with additional exemplary embodiments of the invention; and

FIG. 5 is a flow diagram illustrating a method of operating a component placement system in accordance with an exemplary embodiment of the invention.

### DETAILED DESCRIPTION

As used herein, the term “component” refers to any type of electronic component to be placed by a component placement system. Exemplary components include capacitors, resistors, semiconductor die or chips, etc.

According to certain exemplary embodiments of the invention, a component placement system is provided including one or more placement heads, each of the placement heads including multiple individual pipette cartridges (also referred to herein as “control modules”), which are implemented as a functional exchangeable sub module.

Aspects of the invention provide sensitive electronics at the pipette (or placement assembly including the pipette), and enable modularity within a placement head. As used herein, the term “placement assembly” refers to an assembly including a pipette and a respective control module (where the control module includes a controller for controlling motion of the pipette). Thus, aspects of the invention provide exchangeable placement assemblies that include a control module and a pipette. Such placement assemblies (specific to each pipette) may include integrated sensor and drive electronics.

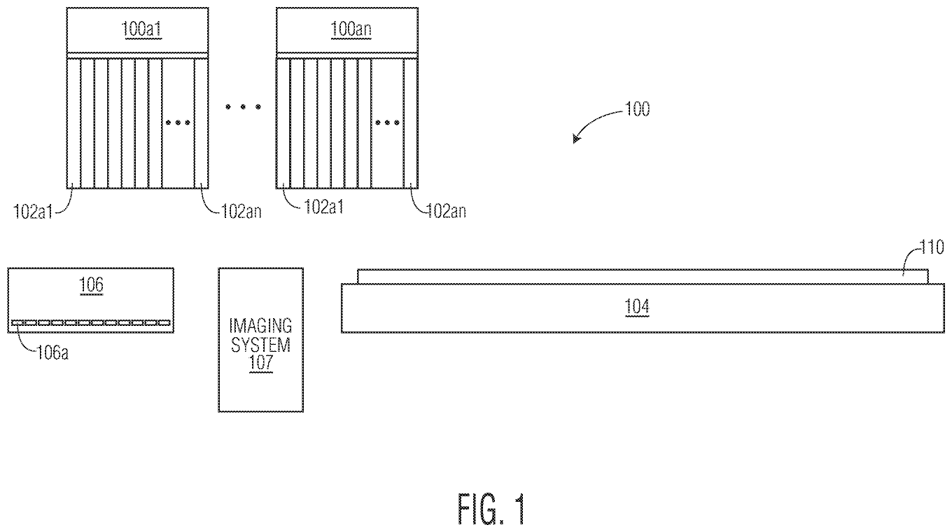

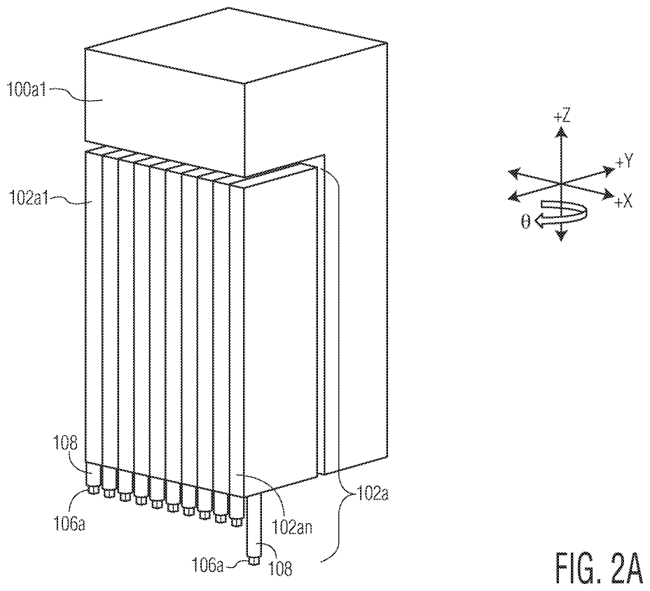

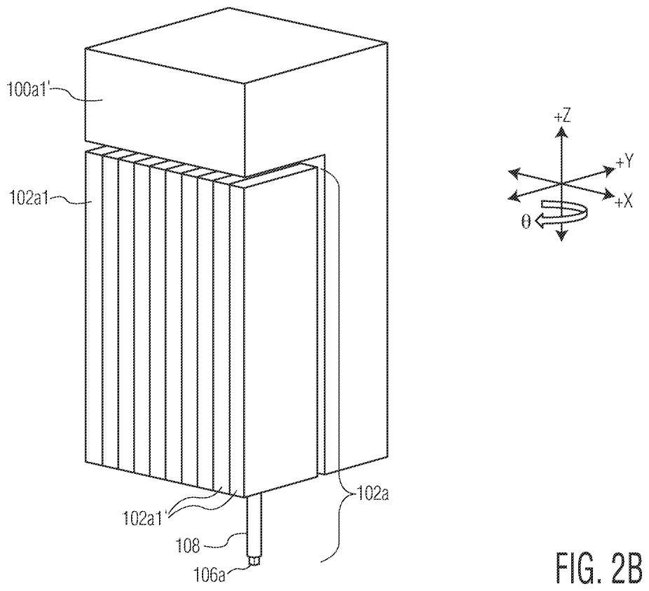

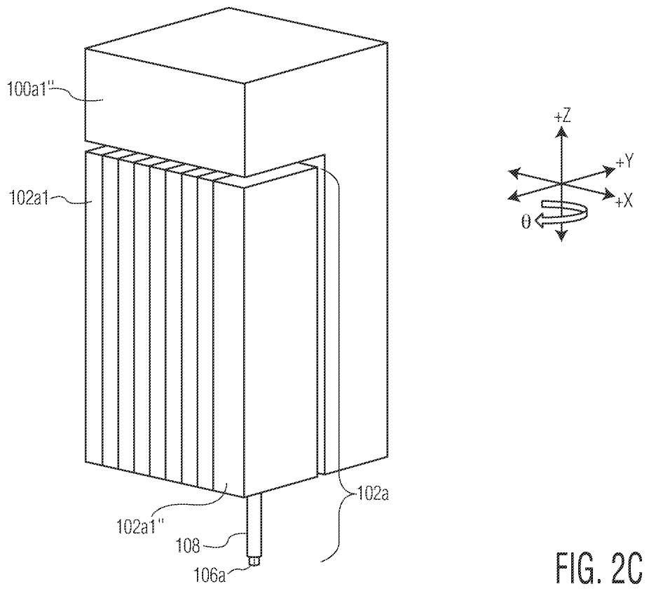

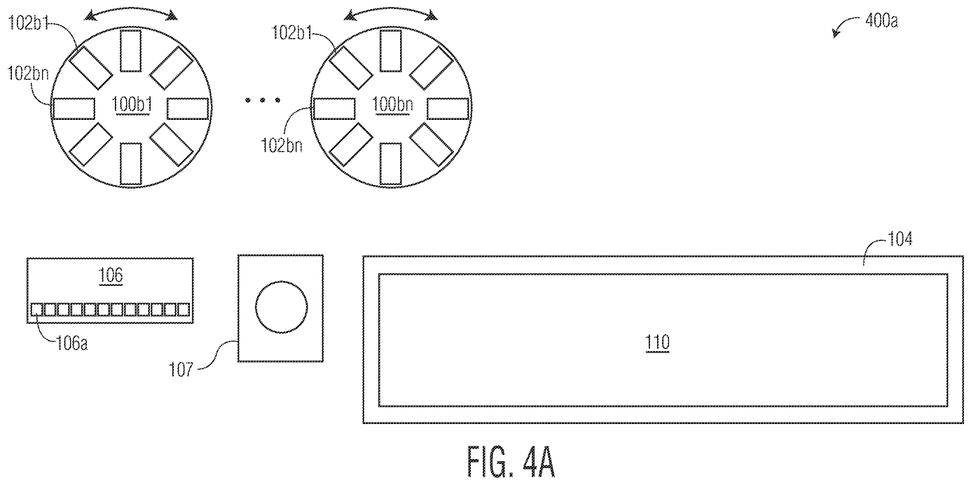

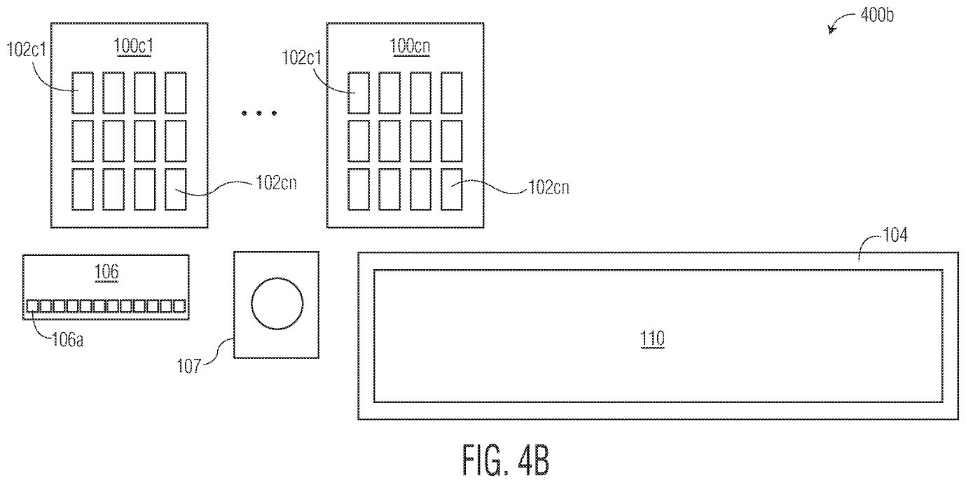

Aspects of the invention relate to placement heads including a plurality of pipettes (and corresponding control modules for each pipette). The pipettes may be arranged in an array configuration (e.g., in a linear array as in FIGS. 1 and 2A-2C, in a matrix array as shown in FIG. 4B, etc.), in an turret configuration (e.g., see FIG. 4A), etc.

In accordance with the invention, each placement head may include (and carry) a plurality of pipettes. For example, a placement head may include: at least 3 pipettes; at least 5 pipettes; at least 10 pipettes; etc.

As will be appreciated by those skilled in the art, a placement head may carry a plurality of components (e.g., one component carried by each of a plurality of pipettes). Typically, a component held by a pipette is rotated and/or generally aligned. Through an inspection process (e.g., using an imaging system including a camera), it may be determined that a component may require further alignment (e.g., using a rotary motor for the given pipette). In accordance with the invention, because each of the pipettes is included in a placement assembly with a respective control module (where the control module controls at least one of z-axis motor current, and theta axis motor current), adjustments may be made in preparation for placing a second component while the placement head is placing a first component. More specifically, while the first component is being placed by a first pipette of the placement head, a relative position of one of more other components held by respective pipettes may be adjusted (e.g., adjusted about a theta axis). In other examples, while a first pipette may be engaged in a pick or place operation (or other motion), z-axis motion of a second pipette (or pipettes) may be commenced. More specifically, in a pick operation, while a first pipette is picking a first component, a second pipette (or pipettes) may begin their descent toward picking another component to save time. Likewise, in a place operation, while a first pipette is placing a first component, a second pipette (or pipettes) may begin their descent toward placing another component (or components) to save time. Of course, such preparation in any of the above examples may be made for multiple components (not just a second component) while picking or placing the first component. This provides for an efficient placement process.

In accordance with aspects of the invention, each pipette may be controlled individually, all of the time. This is important for alignment processes (e.g., using an inspection camera between the component picking process and the component placement process).

Referring now to the drawings, FIG. 1 illustrates a component placement system 100. Component placement system 100 includes a plurality of placement heads 100a1-100an, etc. Each placement head includes a plurality of control modules 102a1-102an configured for carrying pipettes in an array configuration (e.g., see pipettes 108 in

FIG. 2A). Component placement system 100 also includes a component supply 106 including a plurality of components 106a (e.g., where component supply 106 may include a number of component sources, including components of different types, etc.). Component placement system 100 also includes imaging system 107, and support structure 104 for supporting a workpiece 110 (or a plurality of workpieces 110) configured to receive components 106a from pipettes of one or more placement heads 100a1-100an.

Each component placement head 100a1-100an collects components 106a from component supply 106. For example, the various pipettes included in a component placement head (e.g., component placement head 100a1) each collect a respective component 106a (e.g., using vacuum to collect and hold a component 106a). After collecting the components 106a, the component placement head (e.g., component placement head 100a1) moves to a position with respect to imaging system 107 such that a component 106a may be imaged with respect to a part of the pipette (or other part of the control module) carrying that component. In a specific example, the component placement head may be moved to a position above an upward looking camera included in imaging system 107. Imaging system 107 is used to collect positional data (e.g., relative positional data between (i) the component 106a held by a pipette, and (ii) the pipette itself or some other part of the control module). Using this positional data, correction may be made (e.g., adjusted about a theta axis) for accurately placing the component 106a on workpiece 110.

FIG. 2A illustrates placement head 100a1 (e.g., placement head 100a1 from FIG. 1). Placement head 100a1 includes includes a plurality of placement assemblies 102a. Each of the placement assemblies 102a includes one of control modules 102a1-102an, and a corresponding pipette 108 (e.g., where pipette 108 is carried by the respective control module, and where the plurality of pipettes are arranged in an array configuration) (in FIG. 2A, the right most pipette 108 is shown extended further downward as compared to the other pipettes 108). Pipette 108 is illustrated carrying a component 106a. For example, each of control modules 102a1-102an may be the same type of control module (e.g., where such control modules may carry the same type of pipette). However, it is understood that different types of control modules may be carried by placement head 100a1. For example, FIG. 2B illustrates another placement head 100a1′ including control modules 102a1′ (where control modules 102a1′ are different from control modules 102a1-102an from FIG. 2A) (in FIG. 2B, only one pipette 108 is shown, but see FIG. 2A for other pipettes). In another example, FIG. 2C illustrates another placement head 100a1″ including a control module 102a1″ (where control module 102a1″ is different from control modules 102a1-102an from FIG. 2A) (in FIG. 2C, only one pipette 108 is shown, but see FIG. 2A for other pipettes). As shown in FIG. 2C, control module 102a1″ is illustrated as a larger module as compared to control module 102a1. As will be appreciated by those skilled in the art, a larger module may be used to place a larger component 106a, to provide a larger placement force, to carry a larger pipette, etc. For example, the geometry of a pipette 108 may differ depending on the size of the component to be picked and placed. Of course, this is just one example of different types of control modules (and corresponding pipettes). A critical aspect of the invention is that, because of the modular nature of the placement assemblies (including control modules and pipettes) of the placement head, different types of placement assemblies may be utilized in a single placement head.

Thus, in accordance with various exemplary aspects of the invention, a placement head includes modules for placing components of different types, and uses a combination of pipettes with different performance specifications for placement of the components of different types.

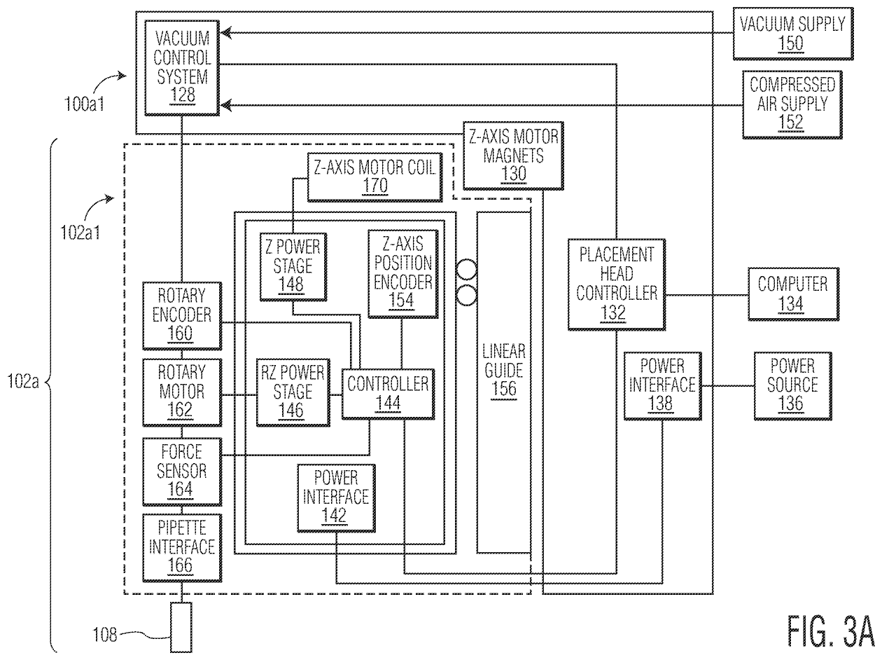

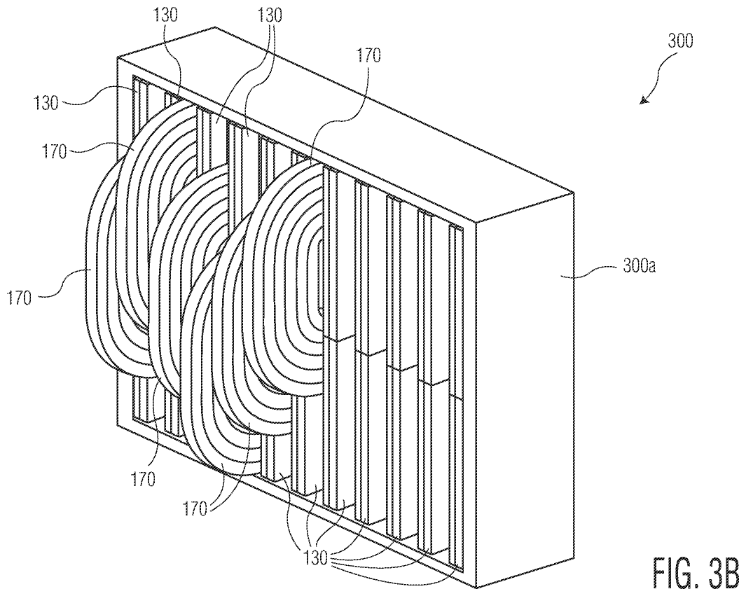

FIG. 3A is a detailed block diagram view of placement head 100a1 (e.g., placement head 100a1 from FIG. 1), including one of the placement assemblies 102a (including one of the plurality of control modules 102a1 and a corresponding pipette 108), as well as other elements of component placement system 100. Certain detailed elements (and functions) of control module 102a1 are also shown.

FIG. 3A illustrates a computer 134 (e.g., a computer included in component placement system 100, a computer external to component placement system 100, etc.) for providing commands to placement head controller 132, and for receiving the status of the commanded actions from placement head controller 132. Thus, placement head controller 132 executes commands received from computer 134 and send the status of commands to computer 134. According to certain embodiment of the invention, placement head controller 132 (e.g., a single placement head controller of placement head 100a1) calculates the move profiles, and/or adapt the move profiles, of a pipette 108—for example, based on feedback (e.g., based on feedback from force sensor 164, to limit the forces on the component during the component handling (picking and placing)). Likewise, according to certain embodiment of the invention, placement head controller 132 calculates the required motor current (e.g., for z-axis motor coil 170 and/or rotary motor 162) based on required position and feedback from the motor encoders (e.g., z-axis position encoder 154 and/or rotary encoder 160).

Thus, in accordance with certain aspects of the invention, placement head controller 132 controls motion trajectories for the each of the plurality of pipettes 108 via communication with the respective one of the plurality of control modules 102a1-102an (through the controller 144 of such control module).

Placement head controller 132 communicates with each of the respective controllers 144 (in corresponding control modules 102a1-102an), by sending current command signals to controller 144, and receiving sensor/encoder data via controller 144. Thus, placement head controller 132 communicates in parallel with each of the control modules 102a1-102an. Placement head controller 132 also communicates with the vacuum control system 128, to control vacuum at each of the pipettes 108.

Thus, in certain exemplary embodiments of the invention, as shown in FIG. 3A, placement head controller 132 controls vacuum for the plurality of pipettes. However, in other embodiments of the invention, each of the plurality of control modules (e.g., control module 102a1-102an) controls vacuum for the respective one of the plurality of pipettes.

Controller 144 (one of which is included in each control module, such as control module 102a1) controls the commanded electrical current signal from placement head controller 132 to each of (i) z-axis power stage 148 (providing the electrical current to z-axis motor coil 170) and (ii) rz power stage 146 (providing the electrical current to rotary motor 162). As such, each of the plurality of control modules 102a1-102an (using controller 144) controls at least one of (i) z-axis motor current control (through z-axis power stage 148) and (ii) theta axis motor current control (through rz power stage 146).

Controller 144 also serializes data (e.g., IO data, position data, force data, etc.) including data from z-axis position encoder 154, rotary encoder 160, and force sensor 164, and provides that data to placement head controller 132. Placement head controller 132 may include, for example, multiple serial interfaces (e.g., one for each pipette and associated placement assembly) that can operate in parallel.

Thus, in accordance with various exemplary aspects of the invention, through their respective controllers 144, each of the plurality of control modules 102a1-102an may be in communication with at least one of (i) a primary motion controller for the placement head (e.g., see placement head controller 132 in FIG. 3A), and (ii) a primary motion controller of the component placement system (e.g., see computer 134 in FIG. 3, acting as a motion controller).

Electrical power is provided to placement head 100a1 (including each of the placement assemblies 102a, and their respective control module 102a1-102an) from an external power source 136. In the exemplary configuration shown in FIG. 3A, power source 136 provides power to placement head 100a1 via power interface 138, where power interface 138 feeds all interval device and components of placement head 100a1. Power is provided to each control module (e.g., control module 102a1) from power interface 138 using respective power interface 142.

An external vacuum supply 150 provides vacuum to placement head 100a1. Vacuum is used to hold a component on pipette 108 through vacuum control system 128. Vacuum control system 128 includes various elements to maintain proper vacuum at pipette 108 (e.g., valves for controlling the vacuum level, blower valves, pressure sensors to measure the vacuum level, etc.). An external compressed air supply 152 provides compressed air to blow off component from pipette 108 (e.g., during placement).

A z-axis motion system 300 (e.g., a linear z-servo motor) is provided for controlling z-axis motion of pipettes 108 (see FIG. 3B). Z-axis motion system 300 includes z-axis motor magnets 130 in housing 300a—where the z-axis motor magnets 130 are included as part of placement head 100a1 for all control modules 102a1-102an of the placement head 100a1. In the illustrated example, the z-axis motor magnets 130 act as the stator part of the z-axis motion system 300. Z-axis motion system 300 also includes a plurality of z-axis motor coils 170 which act as the moving part of z-axis motion system 300. The various z-axis motor coils 170 are included in their respective control module (e.g., control module 102a1).

In the specific implementation shown in FIG. 3A, based on a control signal from controller 144, electrical current is provided from z-axis power stage 148 to a respective z-axis motor coil 170. This electrical current generates a force to move the pipette along the z-axis (i.e., along a vertical axis of component placement system 100). That is, z-axis power stage 148 provides the electrical current running through the z-axis motor coil 170 for the given control module (and associated pipette 108). A z-axis position encoder 154 measures a position along the z-axis (e.g., some relative position to provide position data of the pipette along the z-axis). In the illustrated embodiment in FIG. 3A, a linear guide 156 is provided, for example, to act as a bearing system to guide motion of the pipette along the z-axis.

In the specific implementation shown in FIG. 3A, based on a control signal from controller 144, electrical current is provided from rz power stage 146 (where “rz” means rotation about the z-axis) to rotary motor 162. That is, rz power stage 146 provides the electrical current to rotary motor 162. Rotary motor 162 generates a torque proportional to the electrical current provided by rz power stage 146 to provide for rotation of pipette 108 about the z-axis. Rotary encoder 160 measures a position of rotation around the z-axis, and provides corresponding positional data to controller 144 (where controller 144 is in communication with placement head controller 132, and computer 134).

Force sensor 164 measures the force applied on the component by a pipette 108 during the pick and place actions. Force sensor 164 may include an integrated spring (e.g., a pre-loaded spring) or other flexible element. For example, compression of the integrated spring (or other flexible element) can be measured and translated into a force value. Force sensor 164 may also be used to as a “touch” sensor, for sensing contact between the pipette and a component (at a pick location) and/or for sensing contact between the component and a surface (at a place location). Pipette interface 166 is a mechanical interface to connect pipette 108 to force sensor 164.

The various aspects of component placement system 100 shown in FIG. 1 (and detailed embodiments shown in FIGS. 2A-2C and FIGS. 3A-3B) are not limited to a component placement system having that exact configuration. For example, the concept of different types of placement assemblies (e.g., see FIGS. 2B-2C), or the details shown and described in connection with FIGS. 3A-3B (including details regarding the placement head 100a1, placement assembly 102a, or other details shown in FIGS. 3A-3B), are applicable to component placement systems 400a-400b shown in FIGS. 4A-4B, or any other component placement system within the scope of the invention.

FIG. 4A illustrates another component placement system 400a. Component placement system 400a includes a plurality of placement heads 100b1-100bn. Each placement head includes a plurality of control modules 102b1-102bn configured for carrying pipettes in a turret configuration. Component placement system 400a also includes a component supply 106 including a plurality of components 106a (e.g., where component supply 106 may include a number of component sources, including components of different types), an imaging system 107 (described above in connection with FIG. 1), and a support structure 104 supporting a workpiece 110 (or a plurality of workpieces 110) configured to receive components 106a. Each placement head (e.g., placement head 100b1) is configured to rotate as shown in FIG. 4A for positioning of the relevant control modules (and associated pipette, not shown for simplicity) for pick and place operations.

FIG. 4B illustrates yet another component placement system 400b. Component placement system 400b includes a plurality of placement heads 100c1-100cn. Each placement head includes a plurality of control modules 102c1-102cn configured for carrying pipettes in a array configuration (in FIG. 4B, a matrix array). Component placement system 400b also includes a component supply 106 including a plurality of components 106a (e.g., where component supply 106 may include a number of component sources, including components of different types), an imaging system 107 (described above in connection with FIG. 1), and a support structure 104 supporting a workpiece 110 (or a plurality of workpieces 110) configured to receive components 106a. Each placement head (e.g., placement head 100c1) is configured for motion along a plurality of horizontal axes for positioning of the relevant control modules (and associated pipette, not shown for simplicity) for pick and place operations.

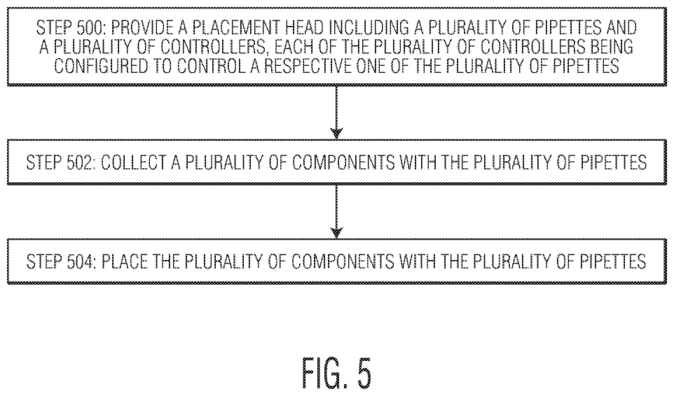

FIG. 5 is a flow diagram illustrating an exemplary method in accordance with the invention. As is understood by those skilled in the art, certain steps included in the flow diagrams may be omitted; certain additional steps may be added; and the order of the steps may be altered from the order illustrated-all within the scope of the invention.

FIG. 5 is a flow diagram illustrating a method of operating a component placement system. At Step 500, a placement head including a plurality of pipettes and a plurality of controllers is provided (e.g., see placement heads 100a1 in FIGS. 1 and 2A and 3, placement head 100a1′ in FIG. 2B, placement head 100a1″ in FIG. 2C, placement head 100b1 in FIG. 4A, and placement head 100c1 in FIG. 4B). Each of the plurality of controllers is configured to control a respective one of the plurality of pipettes. At Step 502, a plurality of components are collected with the plurality of pipettes (e.g., collected from one or more component sources, such as component supply 106). The plurality of components may be collected as desired (e.g., one component being collected at a time, or any other method). After being collected, the plurality of components are held by the placement head, where each component is held by a respective pipette. At Step 504, the plurality of components are placed with the plurality of pipettes. The plurality of components may be placed as desired (e.g., one component being placed at a time, or any other method). For example, one component may be placed by a first pipette while other components are held by other pipettes. While being held by the other pipettes (during placement of the first component), adjustment may be made (e.g., position adjustments, force adjustments, etc.) in preparation for placement of the other components.

While FIG. 3A illustrates a z-axis motion system (not illustrated for simplicity) including z-axis motor magnets 130 carried by one portion of placement head 100a1, and a z-axis motor coil 170 that is part of control module 102a1 (where the control module 102a1 may move with respect to a fixed part of placement head 100a1, for example, along a z-axis), this is just an example of a z-axis motion system, and the invention is not limited thereto.

Various aspects of the invention provide a number of advantages over conventional placement systems such as, for example: higher performance (more accurate motion, lower placement forces, and/or faster due to parallel motion); easy exchangeable spare parts (reducing down time); and configurable pipettes with different performance within one array.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A component placement system comprising:
a placement head including a plurality of pipettes, each of the plurality of pipettes being configured to pick and place components,
the placement head including a plurality of controllers, each of the plurality of controllers being configured to control a respective one of the plurality of pipettes.

2. The component placement system of claim 1 wherein the component placement system includes a plurality of the placement heads, and each of the plurality of placement heads includes at least 3 of the pipettes.

3. The component placement system of claim 1 wherein the plurality of pipettes are arranged in the placement head in at least one of (i) an array configuration and (ii) a turret configuration.

4. The component placement system of claim 1 wherein the placement head includes a plurality of control modules, each of the plurality of control modules including a respective one of the plurality of controllers.

5. The component placement system of claim 4 wherein a placement head controller controls motion trajectories for the each of the plurality of pipettes via communication with the respective one of the plurality of control modules.

6. The component placement system of claim 4 wherein each of the plurality of control modules controls at least one of (i) z-axis motor current control, and (ii) theta axis motor current control.

7. The component placement system of claim 4 wherein each of the plurality of control modules communicates with at least one of (i) a primary motion controller for the placement head, and (ii) a primary motion controller of the component placement system.

8. The component placement system of claim 4 wherein each of the plurality of control modules controls vacuum for the respective one of the plurality of pipettes.

9. The component placement system of claim 4 wherein a placement head controller controls vacuum for the plurality of pipettes.

10. The component placement system of claim 1 wherein the placement head includes a plurality of placement assemblies, each of the plurality of placement assemblies including (i) a control module including a respective one of the plurality of controllers and (ii) a respective one of the plurality of pipettes, each of the placement assemblies including a rotary encoder for detecting a rotary position of the respective one of the plurality of pipettes.

11. The component placement system of claim 1 wherein the placement head includes a plurality of placement assemblies, each of the plurality of placement assemblies including (i) a control module including a respective one of the plurality of controllers and (ii) a respective one of the plurality of pipettes, each of the placement assemblies including a force sensor for detecting an impact force of the respective one of the plurality of pipettes during placement of a component.

12. A component placement system comprising:
a placement head including a plurality of placement assemblies,
each of the plurality of placement assemblies including (i) a controller, (ii) a pipette, (iii) a rotary encoder for detecting a rotary position of the pipette, and (iv) a z-axis position encoder for detecting a z-axis position of the pipette.

13. A component placement system comprising:
a placement head including a plurality of placement assemblies,
each of the plurality of placement assemblies including (i) a controller, (ii) a pipette, and (iii) a force sensor for detecting an impact force of the pipette during placement of a component.

14. A method of operating a component placement system, the method comprising the steps of:
(a) providing a placement head including a plurality of pipettes and a plurality of controllers, each of the plurality of controllers being configured to control a respective one of the plurality of pipettes;
(b) collecting a plurality of components with the plurality of pipettes; and
(c) placing the plurality of components with the plurality of pipettes.

15. The method of claim 14 wherein step (a) includes providing the placement head with the plurality of pipettes being arranged in at least one of (i) an array configuration and (ii) a turret configuration.

16. The method of claim 14 further comprising the step of controlling motion trajectories for the each of the plurality of pipettes via communication between (i) a placement head controller of the placement head and (ii) a respective one of the plurality of controllers.

17. The method of claim 14 further comprising the step of controlling at least one of (i) z-axis motor current control, and (ii) theta axis motor current control using the controller of a respective one of the pipettes.

18. The method of claim 14 further comprising the step of controlling vacuum for each of the plurality of pipettes using a respective one of the controllers.

19. The method of claim 14 further comprising the step of controlling vacuum for the plurality of pipettes using a placement head controller of the placement head.

20. The method of claim 14 wherein the placement head includes a plurality of placement assemblies, each of the plurality of placement assemblies including (i) a control module including a respective one of the plurality of controllers and (ii) a respective one of the plurality of pipettes, each of the placement assemblies including a rotary encoder for detecting a rotary position of the respective one of the plurality of pipettes.

21. The method of claim 14 wherein the placement head includes a plurality of placement assemblies, each of the plurality of placement assemblies including (i) a control module including a respective one of the plurality of controllers and (ii) a respective one of the plurality of pipettes, each of the placement assemblies including a force sensor for detecting an impact force of the respective one of the plurality of pipettes during placement of a component.

22. The method of claim 14 wherein during placement of one of the plurality of components using one of the pipettes, an adjustment is made to a relative position of another of the plurality of components while being held by the respective pipette.
